(19) United States
(12) Patent Application Publication
(10) Pub. No.: US 2026/0037710 A1
(43) Pub. Date: Feb. 5, 2026

(54) MODIFYING INTEGRATED CIRCUIT LAYOUTS IN COMPLIANCE WITH DESIGN RULES

(71) Applicant: GlobalFoundries U.S. Inc., Malta, NY (US)

(72) Inventors: Ivan Krasimirov Kanev, Sofia (BG); Nayden Petkov Nedev, Sofia (BG)

(21) Appl. No.: 18/791,567

(22) Filed: Aug. 1, 2024

(51) Int. Cl. G06F 30/392

(52) U.S. Cl. CPC G06F 30/392

(57) ABSTRACT

The disclosure provides a method for modifying integrated circuit (IC) layouts in compliance with design rules. Methods of the disclosure include identifying, within an integrated circuit (IC) layout, a structure having a physical parameter compliant with a design rule for the layout and exceeding the design rule by a threshold amount. The method includes determining whether modifying the physical parameter for the structure to be less than the threshold amount maintains compliance with the design rule. In response to determining that modifying the physical parameter maintains compliance with the design rule, the method includes modifying the IC layout and transmitting the modified IC layout to a manufacturing device.

### BACKGROUND

The present disclosure relates to integrated circuit (IC) fabrication. More specifically, the present disclosure relates to methods, program products, and systems to process layouts for IC fabrication.

Fabrication foundries (“fabs”) manufacture ICs using photolithographic processes. Photolithography is an optical printing and fabrication process by which patterns on a photolithographic mask (simply “mask” hereafter) are imaged and defined onto a photosensitive layer coating of a substrate. To manufacture an IC, masks are created using an IC layout as a template. The masks contain the various geometries of the IC layout, and these geometries may be separated with layers of photoresist material.

Through sequential use of the various masks corresponding to a given IC in an IC fabrication process, a large number of material layers of various shapes and thicknesses with different conductive and insulating properties may be built up to form the overall IC and the circuits within the IC layout. Requirements for surface area, structure density, and component size in an IC product may pose technical challenges. Such challenges may include certain design rules (i.e., manufacturing constraints for ensuring manufacturability of a device) imposing stronger limits than necessary for spacing between certain structures within the IC layout. Conventional processing techniques do not allow modification of a layout for different technical purposes if a layout is non-compliant, or is close to being non-compliant, with a design rule.

### SUMMARY

Aspects of the disclosure provide a method including: identifying, within an integrated circuit (IC) layout, a structure having a physical parameter compliant with a design rule for the layout, and exceeding the design rule by a threshold amount; determining whether modifying the physical parameter for the structure to be less than the threshold amount maintains compliance with the design rule; and in response to determining that modifying the physical parameter maintains compliance with the design rule: modifying the IC layout, and transmitting the modified IC layout to a manufacturing device.

Further aspects of the disclosure provide a computer program product stored on a computer readable storage medium, the computer program product including program code, which, when being executed by at least one computing device, causes the at least one computing device to: identify, within an integrated circuit (IC) layout, a structure having a physical parameter compliant with a design rule for the layout and exceeding a design rule for the structure by a threshold amount; determine whether modifying the physical parameter for the structure to be less than the threshold amount maintains compliance with the design rule; and in response to determining that modifying the physical parameter maintains compliance with the design rule: modify the IC layout, and transmit the modified IC layout to a manufacturing device.

Additional aspects of the disclosure provide a system including: a computing device; an I/O component operatively coupled to the computing device; and a memory operatively coupled to the computing device, wherein the computing device includes logic and is configured to perform a method including: identifying, within an integrated circuit (IC) layout, a structure having a physical parameter compliant with a design rule for the layout, and exceeding a design rule for the structure by a threshold amount; determining whether modifying the physical parameter for the structure to be less than the threshold amount maintains compliance with the design rule; and in response to determining that modifying the physical parameter maintains compliance with the design rule: modifying the IC layout, and transmitting the modified IC layout to a manufacturing device.

### BRIEF DESCRIPTION OF THE DRAWINGS

FIG. 1 provides a diagram of a portion of an IC layout according to embodiments of the disclosure.

FIG. 2 provides a schematic diagram of a components for implementing a method according to embodiments of the disclosure.

FIG. 3 depicts an example of a non-modified IC layout according to embodiments of the disclosure.

FIG. 4 depicts an example group of structures having physical parameters indicated as exceeding or not exceeding a design rule by a threshold amount in methods according to the disclosure.

FIG. 5 depicts an example of a modified IC layout according to embodiments of the disclosure.

FIG. 6 depicts a schematic view of an illustrative environment including a computing device for implementing methods according to the disclosure.

FIG. 7 depicts an example interface for displaying whether structures in an IC layout exceed design rules by a threshold amount in methods according to the disclosure.

FIG. 8 provides an example flow diagram for an operational methodology for implementing methods according to embodiments of the disclosure.

FIG. 9 provides an example flow diagram for an operational methodology for implementing methods according to further embodiments of the disclosure.

It is noted that the drawings of the disclosure are not necessarily to scale. The drawings are intended to depict only typical aspects of the invention, and therefore should not be considered as limiting the scope of the invention. In the drawings, like numbering represents like elements between the drawings.

### DETAILED DESCRIPTION

In the following description, reference is made to the accompanying drawings that form a part thereof, and in which is shown by way of illustration specific exemplary embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

The disclosure provides a method for modifying integrated circuit (IC) layouts in compliance with design rules. An IC refers to an electronic circuit formed on semiconductor material that is configured implement various electronic circuits and/or related functions. Methods of the disclosure include identifying, within an integrated circuit (IC) layout, a structure having a physical parameter compliant with a design rule for the layout and exceeding the design rule by a threshold amount. The method includes determining whether modifying the physical parameter for the structure to be less than the threshold amount maintains compliance with the design rule. In response to determining that modifying the physical parameter maintains compliance with the design rule, the method includes modifying the IC layout and transmitting the modified IC layout to a manufacturing device.

To better illustrate the various embodiments of the present disclosure, particular terminology which may be known or unknown to those of ordinary skill in the art is defined to further clarify the embodiments set forth herein. The term “system” refers to a computer system, server, etc. composed wholly or partially of hardware and/or software components, one or more instances of a system embodied in software and accessible a local or remote user, all or part of one or more systems in a cloud computing environment, one or more physical and/or virtual machines accessed via the internet, other types of physical or virtual computing devices, and/or components thereof. The terms “layout” or “mask layout” refer to a complete or partial mapping of masking material to be used for forming (e.g., by various combinations of etching, deposition, etc.) a particular layer which includes multiple structures (also known as “features”).

A “PDK” refers to any user-defined characteristic(s) for distinguishing masks that are viable for manufacture from masks that are not viable for manufacture. PDKs may include a comprehensive listing of such measurements, including for example design structures, dimensions of particular regions, desired amounts of space to be occupied by fill cells, performance requirements, etc., for all measurable aspects of a device to be manufactured. However, rules in a PDK for determining whether particular layers are compliant or non-compliant with manufacturing requirements are particularly relevant to embodiments discussed herein. In the example of a front end of line (FEOL) layer (i.e., layers of a device formed before the first metallization and including device components such as transistors, resistors, capacitors, etc.).

A PDK may include a “mask rule” for the layer to be produced. Mask rules refer to dimensional requirements and other measurements for determining whether a particular mask will cause mask inspection problems. In the example of a back end of line (BEOL) layer, i.e., layers of a device after the first metallization, e.g., layers containing wires and vias for coupling functional components together, a PDK may include a “design rule” for the layer to be produced. Design rules refer to minimum dimensions of devices and interconnects to be formed in an integrated circuit adopted during the design stage and determined by the capabilities of process technology available. Mask rules and design rules are distinct from each other, e.g., by using different types of information about a layout to determine its compliancy or non-compliancy. Mask rules in particular examine an entire mask layout and the spatial relationship between multiple patterns in their final orientation, scale, and tone. In contrast, design rule analysis is usually performed on individual pattern files which may be used to form layouts.

The layout for a particular mask may be obtained from design data and/or generated, modified, etc., with the aid of optical proximity correction (OPC) or other design-enhancement systems. A “structure,” or alternately “feature,” generally refers to a functional element in an IC product (e.g., a wire, waveguide, and/or other element for transmitting electricity, radiation, etc.) which must be printed on a wafer using photolithography techniques. A “region” refers to any subset of a given mask. A “pattern” or “feature pattern” refers to a design layout representation of one or more portions of a mask which define the structures to be formed in a particular IC product, and which may be formed with the aid of a mask by way of, for example, direct-write electron beam lithography. The patterns in a mask may be structured and positioned to cover underlying materials, and thereby protect them from being etched away while other portions of a layer are being removed.

A “margin” refers to an additional amount of distance added to the minimum size of a structure (e.g., length, width, etc., generally known as “critical dimension”) and a separation distance from an adjacent feature along the same dimension to account for process variations when manufacturing the feature(s) in an IC layout. Design rules for an IC layout may prescribe a minimum margin for two adjacent structures based on, e.g., the types of structures being formed and/or the location of those patterns within the IC layout. For each pair of adjacent structures in an IC layout, one or more margins may be calculated for various pairs of structures and/or dimensions. The number of margins and/or directional orientations may differ depending which two adjacent structures are being compared, e.g., an uppermost point on one axis may be used for calculating the margin with an adjacent structure along that axis, whereas a leftmost point or rightmost point on a different axis may be used for calculating the margin for the same structure with a different adjacent structure along that axis.

In modern IC design and manufacture, merely complying with design rules for a product may not include taking advantage of additional opportunities for further compaction of the design, particularly when such compactions still comply with the design rules for an IC layout, because such compactions may violate design rules for the layout. Embodiments of the disclosure provide additional analysis tools to identify opportunities for further compaction of structures within an IC layout by targeting adjacent with physical parameters exceeding design rules by particular amounts (i.e., a threshold value) and modifying the layout to bring those physical parameters below the threshold value. The layout is then re-analyzed for compliance with design rules, and submitted for manufacture in the case where the modified layout maintains compliance with the design rules. Embodiments of the disclosure thereby produce various technical effects, etc., products that are manufactured to include a higher structure density than would otherwise be possible through conventional design rule check (DRC) and optical proximity correction (OPC) techniques.

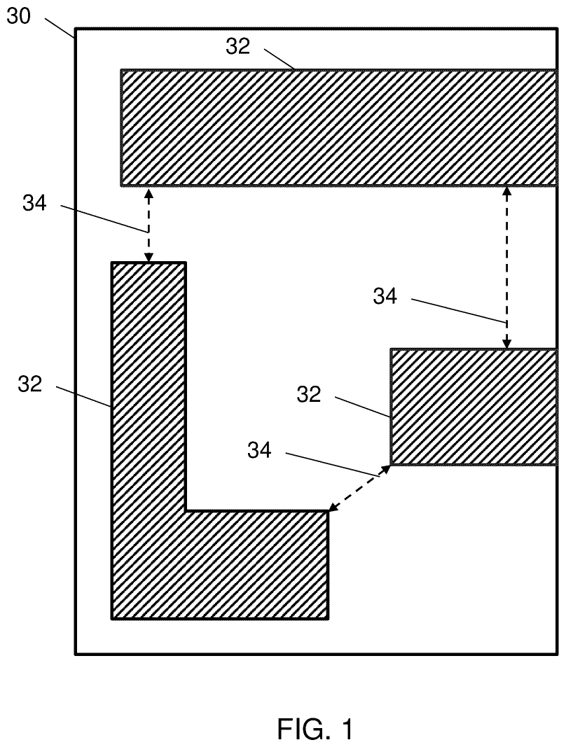

FIG. 1 illustrates a plan view of an IC layout (“layout” hereafter) 30 in plane X-Y, representing at least a portion of a mask to be used in the manufacture of one or more devices. Layout 30 may encompass a given surface area in plane X-Y, and only a portion of layout 30 is shown in FIG. 1 to better illustrate various aspects of structures 32 that may be included within layout 30. Layout 30, furthermore, depicts only one layer of an IC product to be manufactured. Other layers of the same product may be depicted in separate layers, and thus, certain structures 32 in layout 30 that appear to be isolated from each other may be interconnected through other structures that appear in different layers but are not depicted in layout 30.

At a high level of generality, layout 30 may include any combination of structures 32, each of which may have any conceivable shape and/or size. Various structures 32, for example, may represent transistors, capacitors, resistors, waveguides, inductors, wires, diodes, etc. Although structures 32 are shown by example as having essentially linear edges, it is understood that in various implementations one or more structures 32 of IC layout 30 may include curvilinear edges, shapes, etc., and the linear edges of structures 32 shown are solely for ease of illustration. Methods of the disclosure pertain to analyzing structures 32 in layout 30 (including those already deemed compliant with design rules) to identify opportunities for compaction of structures 32 within layout 30, creating modified, compacted versions of layout 30 to reduce surface area of a design, and instructing a manufacturing device to create devices from any layouts modified for compaction of structures 32 where possible.

FIG. 1 also depicts separation distances 34 between adjacent structures 32. Structures 32 are considered “adjacent” if a line connecting a reference point from one structure 32 to another reference point of another structure 32 does not pass through any structures 32 located therebetween. Each separation distance 34 does not indicate physical space on a manufactured product, but rather, is a prediction for the amount of physical distance between adjacent structures 32 based on design rules for layout 30. It is understood that some structures 32 may not be adjacent along one connecting line but may be considered adjacent along one or more other connecting lines. In the illustrated example, structures 32 of layout 30 are pre-determined (e.g., in earlier, conventional phases of processing and/or analysis) to be compliant with applicable design rules for a product to be manufactured. Some separation distances 34 in layout 30, when combined with the corresponding dimension(s) of structure(s) 32, may exceed the critical dimension for manufacturability of layout 30 by a significant amount. Rather than simply checking for violations of design rules (e.g., structures 32 and separation distances 34 that violate the critical dimension), embodiments of the disclosure identify and propose modifications to portions of layout 30 that exceed design rules by a threshold amount. For purposes of this disclosure, the concept of “exceeding a design rule by a threshold amount” to a state between adjacent structures 32 where a difference between a predicted value of the physical parameter under analysis in layout 30 (e.g., separation distance) and a critical value for that physical parameter (as set by a design rule) is greater than a threshold amount. When such a state is identified, the potential for making a design modification (e.g., to achieve compaction) is also identified. Thus, where possible, embodiments of the disclosure are operable to modify layout 30 for compaction and thereby cause structures 32 to occupy a smaller surface area.

In embodiments of the disclosure, “minimum separation” refers to the smallest possible distance between adjacent structures 32 in layout 30 while maintaining manufacturability. The minimum separation may be defined by physical parameters of any tools, equipment, etc., for manufacturing a product from layout 30. A “margin” refers to an estimated additional distance, greater than the minimum separation distance, to account for process variations when manufacturing a device from layout 30. The size of structure 32 in one direction plus the minimum separation yields the “critical dimension” for a portion of layout 30. The critical dimension may vary depending on the structure(s) 32 to be manufactured and the direction being measured. For instance, the critical dimensions of a particular structure 32 may be different lengthwise, widthwise, diagonally, etc.

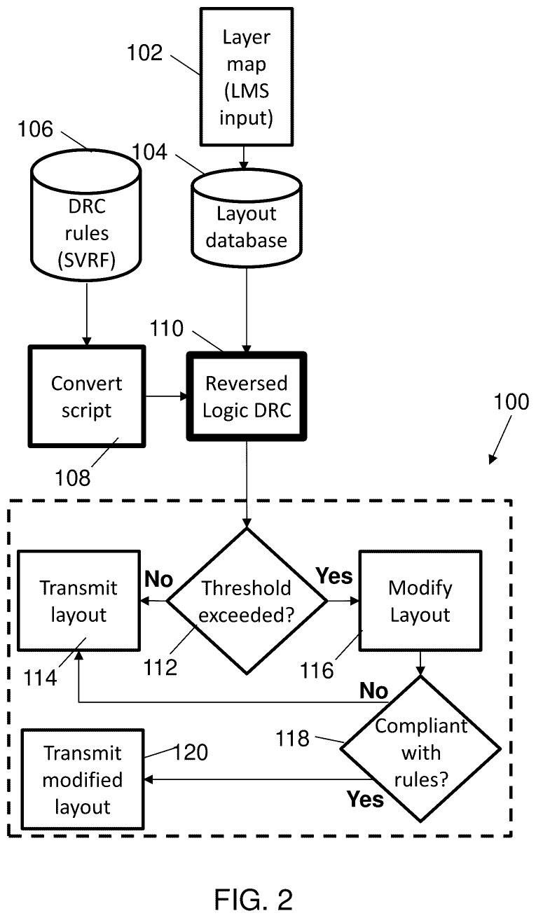

Referring to FIGS. 1 and 2 together, methods of the disclosure convert design rule check (DRC) logic for analyzing non-compliance with design rules into a methodology for identifying excessive compliance with design rules, i.e., structures 32 and separation distances 34 that exceed threshold amounts for their respective dimensions. Moreover, embodiments of the disclosure proposed modifications any portions of layout(s) 30 that exceed the threshold amount(s) to determine whether a modified version of layout(s) 30 will remain compliant with any design rules under analysis. FIG. 2 provides a schematic diagram of an example set of components and operations for implementing a method 100 according to the disclosure. Other FIGS. discussed herein provide a more detailed explanation of various components and processes shown in FIG. 2.

Various catalogues of data may be accessed (e.g., transmitted, calculated, copied, and/or otherwise provided via any currently known or later developed technique for accessing data) to implement embodiments of method 100. For instance, a layer map 102 (e.g., a set of multiple layouts 30 for various processing layers provided in a text format, graphic design system (“GDS”) format, or other formats) may be data representing a set of layouts 30 (FIG. 1) for manufacturing a particular product or portion thereof. Layer map 102 may be filtered to provide only a subset of layouts 30 for processing, e.g., a filter function within a layout management system (LMS) may remove maps and/or portions thereof with any structures 32 or other characteristics that make a particular layout 30 unsuitable for processing. Multiple layer maps 102 may be provided, stored, etc., in a layout database 104. Layout database 104 may include layer maps 102 for multiple groups of products, individual products, and/or distinct layers within a particular product. Layout database 104 in some cases may be the same as, or otherwise may include or may have access to, a training data library of proposed layouts 30 and/or predicted layouts 30 for products that may be manufacturable in various other conceivable situations.

Method 100 also may have access to a repository of design rule check (DRC) rules 106, i.e., the individual rules analyzed for a particular layout 30 or portion thereof to indicate whether that layout 30 is manufacturable with available manufacturing tools. DRC rules 106 may be provided in any conceivable format, e.g., standard verification rule format (SVRF) language and/or other languages, formats, etc., for recording design rules for analyzing and evaluating structures 32, separation distances, 34, etc., in layout 30 for manufacturability. In conventional processing, DRC rules 106 are simply cross-referenced with any layout(s) 30 under analysis to determine whether a particular product or portion thereof is manufacturable. In embodiments of the disclosure, DRC rules 106 are instead used together with layout(s) 30 of layout database 104 to determine whether any layout(s) 30 can be modified such that structures 32 thereof may be placed closer together to occupy a smaller surface area than would otherwise be needed.

Initially, DRC rules 106 may be in a format different from and/or incomparable with the representation(s) provided in layer map(s) 102 and/or layout database 104. In operation 108, DRC rules 106 may be converted from an initial format (e.g., SVRF as discussed herein) to a reversed logic design rule check (DRC) 110. Reversed logic DRC 110 is “reversed” in the sense that it checks for structures 32 that comply with DRC rules 106 and does not specifically identify any structures 32 that violate DRC rules 106 as provided in conventional analysis.

Reversed logic DRC 110 may provide control logic and/or other analysis technique to determine whether any or all structures 32 in layout 30 comply with DRC rules 106, and in addition, whether the same or related attributes of structure(s) 32 exceed the requirements for certain DRC rules 106 by a threshold amount. In one example, DRC rules 106 may define a minimum separation distance of approximately thirty nanometers (nm) between two adjacent structures 32. Reversed logic DRC 110 may add a calculated and/or predetermined additional threshold value to the minimum separation distance, e.g., ten nm. Reversed logic DRC 110 thereby provides an analytical framework to determine whether two adjacent structures 32 comply with DRC rules 106 and exceed DRC rules 106 by the threshold value. Any structure(s) 32 and/or other aspects of layout 30 exceeding the threshold may be modified to have different positions, sizes, and/or other physical parameters in subsequent phases of processing. Reversed logic DRC 110 thereby sets two phases of analysis for layout(s) 30 and structure(s) 32 therein: whether various portions of layout 30 comply with DRC rules 106, and whether the same portions of layout(s) 30 and/or structure(s) 32 exceed DRC rules 106 by threshold amounts. Reversed logic DRC 110 thereby enables implementing method 100 with various operations 112, 114, 116, 118, 120 discussed herein.

In method 100, operation 112 includes determining via reversed logic DRC 110 whether any structure(s) 32 or other aspects of layout(s) 30 exceed requirements in DRC rules 106 by a threshold amount. For instance, operation 112 may include determining whether two structures 32 separated by at least a minimum separation distance (e.g., thirty nm in the above example) by a threshold value (e.g., ten nm in the above example). In cases where the threshold value is not exceeded (i.e., “No” at operation 112), the method may proceed to operation 114 of transmitting layout 30 to a fabrication tool for manufacture without further modification. In operation 114, layout 30 is transmitted without the proposed modifications under analysis and thus is considered to be a non-modified layout. Operation 114, in some cases, may include flagging or “marking off” layout 30 and/or structures 32 therein as not being capable of further compaction, e.g., to prevent re-analysis of layout 30 in fabrication and/or analysis of subsequent products. In cases where structure(s) 32 and/or portions of layout 30 exceed the threshold value (i.e., “Yes” at operation 112), the method may instead proceed to operation 116 of modifying layout 30. Operation 116 may include simply changing the size, shape, location, etc., of structures 32 in layout 30 by predetermined or user-chosen amounts. In further examples, operation 116 may include automatically generating one or more proposed modifications to layout 30 based on the physical parameters under analysis, the amount by which such attributes exceed their respective threshold(s), etc.

Further processing in operation 118 may consider whether layout 30, portions thereof, and/or structure(s)S 32 remain compliant with DRC rules 106 after the modifying in operation 116. For instance, adjusting the shape, size, position, etc., of some structure(s) 32 may remain complaint with certain DRC rules 106 under consideration but may unintentionally violate other DRC rules 106. According to an embodiment, changing the position of one structure 32 to be closer to an adjacent structure may also move the same structure 32 too close to another structure 32, thereby violating other DRC rules 106 for layout 30. Where the modified layout(s) 30 is/are not compliant with DRC rules 106 (i.e., “No” at operation 118), the method may proceed by transmitting the non-modified layout in operation 114 as discussed herein. Where the modified layout(s) 30, portions thereof, and/or structure(s) 32 are compliant with DRC rules 106 after modifying layout(s) 30 and/or structure(s) 32 (i.e., “Yes” at operation 118), the method may proceed to operation 120 of transmitting the modified layout for manufacture. Operation 120, in some cases, may include flagging or “marking off” layout 30 and/or structures 32 therein as having been modified for further compaction, e.g., to prevent re-analysis of layout 30 in fabrication and/or analysis of subsequent products. Moreover, layout(s) 30 and or structure(s) 32 modified in operation 116 and deemed compliant with DRC rules 106 in operation 118 may be associated in data as being a modified version of other layout(s) 30 and/or structure(s) 32 for ease of indexing and/or to accelerate subsequent analysis and/or processing of similar layout(s) 30 or structure(s) 32.

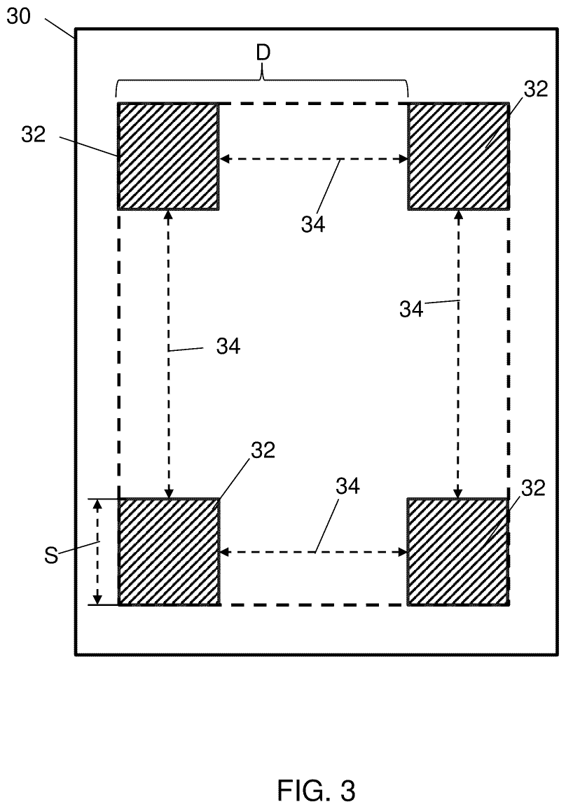

Referring to FIGS. 2 and 3 together, in which FIG. 3 depicts a schematic diagram of an example layout 30, an example of various operational details in method 100 (FIG. 2) is discussed. Four structures 32 are shown in layout 30 of FIG. 3 as an example, but structures 32 shown in FIG. 3 may represent only a portion of all structures 32 in layout 30, and/or may indicate one portion of layout 30 presently under analysis. Adjacent structures 32 each may be separated from each other by respective separation distances 34 in layout 30. Each structure 32 and/or portion of layout 30 may have various physical properties. For instance, one structure 32 may have a pitch D indicated by the sum of its width along one axis and separation distance 34 from another structure 32 along the same axis. For layout 30 to be manufacturable, pitch D may need to comply with a critical dimension for layout 30 specified in DRC rules 106. Similarly, one or more structures 32 may have a dimension S (e.g., a length, width, and/or other distance indicating the size of structure 32 from one point to another). Attributes such as pitch D, dimension S, and/or other properties (e.g., separation distances 34 themselves, surface area, etc.) for structures 32 in layout 30, initially, may be compliant with DRC rules 106 before processing in method 100 occurs. Thus, layout 30 as shown in FIG. 3 may indicate a portion of layout(s) 30 deemed compliant with DRC rules 106 and considered for further compaction via embodiments of method 100.

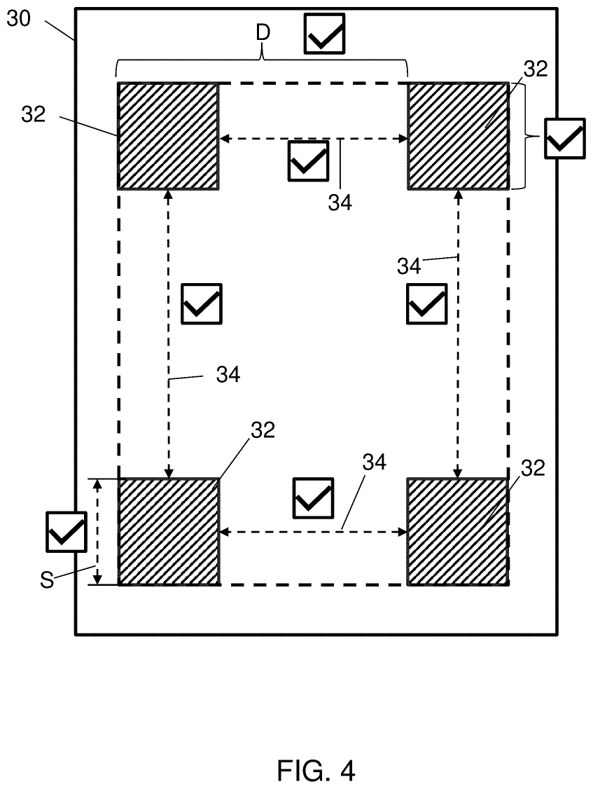

Referring now to FIGS. 2 and 4, methods 100 may include evaluating in operation 112 whether various physical parameters of structure(s) 32 exceed relevant DRC rules 106 by at least a threshold amount. The term “physical parameter,” as used herein, may refer to any positional or spatial quantity of individual structure(s) 32 in layout 30 or similar quantity pertaining to two or more structure(s) 32. As examples, physical parameters may include a dimension (e.g., length, width, perimeter, etc.), spacing (e.g., separation distance 34 or other spatial quantity pertaining to multiple structures 32), a surface area, an enclosure (e.g., amount of vacant or non-vacant surface area enclosed by other surrounding structures 32), and overlap (e.g., amount of surface area covered by two or more features located in different layers of a device), an overlap relative to dimensionality (e.g., comparison between overlap and one or more dimensions for structure(s) 32 under analysis), and/or other of such quantities. FIG. 4 provides an annotated view of layout 30 in which any structures 32 exceeding the threshold amount are indicated with “check marks,” i.e., they comply with DRC rules 106 and exceed those rules by at least the threshold amount specified in reverse logic DRC 110. For instance, each dimension S is deemed to exceed a design rule for minimum dimension by at least a threshold number of nanometers. In this case, structures 32 may be resized to have a smaller dimension S that still complies with DRC rules 106. Similarly, each separation distance 34 between adjacent structures 32 in the example of layout 30 may exceed a design rule for separation distances within layout 30 by a threshold amount, and thus each separation distance 34 is indicated with a check mark. Any structures 32, separation distances 34, and/or other aspects of layout 30 not exceeding the threshold value but compliant with DRC rules 106 may be flagged as not suitable for further compaction and thus not further processed. In further implementations, any structures 32, separation distances 34, and/or other aspects of layout 30 not exceeding the threshold value but compliant with DRC rules 106 may be visually indicated with a different symbol (e.g., an X, O, or other identifier) to better communicate why certain aspects of layout 30 cannot be modified in subsequent processing.

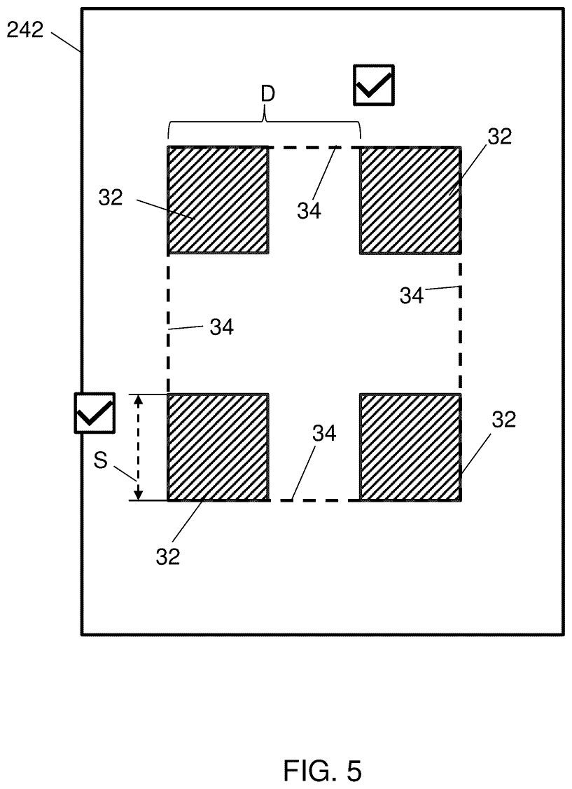

FIG. 5 depicts an example of modified layout 242 produced, e.g., by reducing separation distances 34 between adjacent structures 32 and reducing the dimension S (e.g., length and/or width) of individual structures 32 in layout 30. Modified layout 242 may be produced, e.g., by automatically moving individual structures 32 and/or changing any dimensions that define dimension S by predetermined about. Method 100 as discussed herein may include further analyzing modified layout 242 for compliance with DRC rules 106. For instance, DRC rules 106 may include a minimum size for dimension(s) S of each structure 32 and/or a critical dimension for pitch D between adjacent structures 32. In the example of FIG. 5, dimension S and pitch D remain compliant with design rules 106 after modified layout 242 is created (i.e., they are both indicated with check marks in FIG. 5). Thus, modified layout 242 is capable of being manufactured, and may occupy a smaller surface area than layout 30 in its original form. Thus, creating modified layout 242 from layout 30 in method 100 may reduce a surface area of any manufactured layouts relative to their original form. In an alternative example, where either or both of dimension S or pitch D are not compliant with design rules 106, layout 30 may be manufactured instead of modified layout 242 and/or another modified layout 242 with different modifications may be analyzed instead. The view of layout 30 and/or modified layout 242 depicted in FIGS. 4 and 5, moreover, may displayed on a user interface to allow a user to select whether layout 30 or any modified layouts 242 will be manufactured. In this case, the interface may simply omit any modified layouts 242 deemed to not comply with design rules 106.

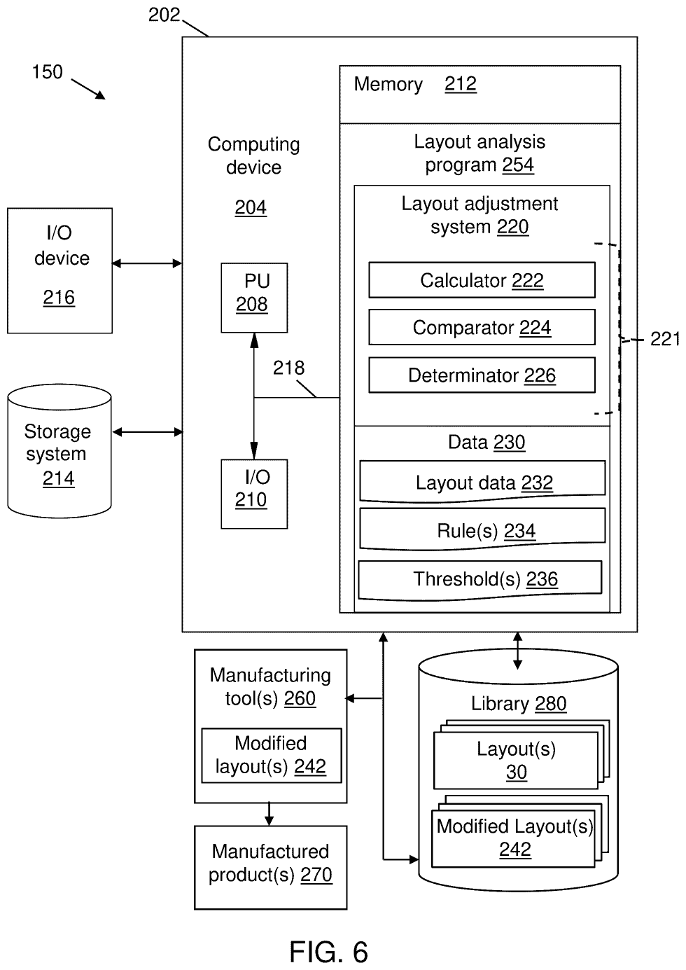

Referring to FIGS. 1 and 6 together, an illustrative environment 150 (FIG. 6 only) for implementing the methods and/or systems described herein is shown. In particular, a computer system 202 is shown to include computing device 204. Computing device 204 may include, e.g., a layout analysis program 254 which may include, e.g., one or more sub-systems such as layout adjustment system 220, for performing any/all of the processes described herein and implementing any/all of the embodiments described herein.

Environment 150 may include manufacturing tool(s) 260 (e.g., a single manufacturing tool and/or a group of interconnected devices) configured to create manufactured product(s) 270 from modified layout(s) 242 (i.e., layout(s) 30 modified in embodiments of method 100 discussed herein). Manufactured product(s) 270 may be manufactured from modified layout(s) 242 having structures 32 in positions that are closer together than an initial, non-modified version of layout(s) 30 while retaining compliance with any rule(s) 234 (e.g., DRC rules 106 FIG. 2) and/or reversed logic DRC 110 (FIG. 2)) specified in data 230. Environment 150 may also include a library 280 for storing layout(s) 30 and/or modified layout(s) 242. In accordance with embodiments of the disclosure, library 280 is connected to and modified by a layout analysis program 254 including, e.g., one or more systems for creating modified layout(s) 242 from layout(s) 30. Library 280 may be distinct from data 230, e.g., by being one or more remote data repositories accessible to multiple layout analysis program(s) 254. Layout analysis program 254 may be implemented, e.g., in a computer system 202, and the various systems and modules therein may operate through one or more processing techniques described herein. Layout analysis program 254 may select particular layout(s) 30 for analysis and to change the position of structures 32 in layout(s) 30 to create modified layout(s) 242 as discussed herein. Computer system 202 may be in communication with library 280, e.g., according to any currently-known or later developed solution for communicating between data repositories (e.g., library 280), computer systems (e.g., computer system 202), and/or other data repositories discussed herein.

Computer system 202 can aid in the design and manufacture of IC products by causing manufacturing tool(s) 260 to create manufactured product(s) 270 from layout(s) 30 and/or modified layout(s) 242, and/or converting one or more layout(s) 30 into modified layout(s) 242. The modifying of layout 242 may be accomplished by changing the position of certain structures within layout 30 to reduce the separation distance between adjacent structures, after confirming that modifying the location of structure 32 in this manner complies with design rules. The modifying layout 242 in addition or alternatively may include proposing multiple modifications to layout 30 and displaying these proposals to a user for selection or rejection, e.g., allowing manual adjustment of layout 30 to create modified layout(s) 242 via a user interface. Modified layout(s) 242, when created and/or applicable, may occupy less surface area than the initial layout(s) 30 by moving adjacent structures 32 closer together Layout analysis program 254 may perform functions discussed herein, e.g., by processing data from library 280 for one or more layouts 30. Layout analysis program 254 may generate instructions for adjusting manufacturing tool(s) 260, based on the location of structures in modified layout(s) 242. Modified layout(s) 242 may be stored, e.g., in memory components of computer system 202 for future use. Example procedures for modifying layout 30 to create modified layout 242 are provided in further detail below.

Computer system 202 is shown including a processing unit (PU) 208 (e.g., one or more processors), an I/O component 210, a memory 212 (e.g., a storage hierarchy), an external storage system 214, an input/output (I/O) device 216 (e.g., one or more I/O interfaces and/or devices), and a communications pathway 218. In general, processing unit 208 may execute program code, such as layout analysis program 254, which is at least partially stored in memory 212. While executing program code, processing unit 208 may process data, which may result in reading and/or writing data from/to memory 212 and/or storage system 214. Pathway 218 provides a communications link between each of the components in environment 150. I/O component 210 may include one or more human I/O devices, which enable a human user to interact with computer system 202 and/or one or more communications devices to enable a system user to communicate with the computer system 202 using any type of communications link. To this extent, layout analysis program 254 may manage a set of interfaces (e.g., graphical user interface(s), application program interface(s), etc.) that enable system users to interact with layout analysis program 254. Further, layout analysis program 254 may manage (e.g., store, retrieve, create, manipulate, organize, present, etc.) data, through several modules contained within a layout adjustment system 220. Layout adjustment system 220 is shown by example as being a sub-system of layout analysis program 254.

As noted herein, layout analysis program 254 may include layout adjustment system 220. In this case, various modules (calculator 222, comparator 224, and determinator 226, collectively “modules”) of layout adjustment system 220 may enable computer system 202 to perform a set of tasks used by layout analysis program 254 and may be separately developed and/or implemented apart from other portions of layout analysis program 254. Calculator 222 can implement various mathematical computations in processes discussed herein. Comparator 224 can compare two quantities and/or items of data in processes discussed herein. Determinator 226 may, e.g., make logical determinations based on compliance or non-compliance with various conditions (e.g., structures 32 and/or modifications to structure 32 complying or not complying with design rules) in processes discussed herein. One or more modules 222, 224, 226, may use algorithm-based calculations, look up tables, software code, and/or similar tools stored in memory 212 for processing, analyzing, and operating on data to perform their respective functions. Each module discussed herein may obtain and/or operate on data from exterior components, units, systems, etc., or from memory 212 of computing device 204.

Layout analysis program 254 may also include a catalogue of data, rules, and/or other aspects of a product to be manufactured, expressed as data 230 which may define, e.g., the various characteristics of layout(s) 30 and/or acceptable design characteristics and manufacturing parameters for layout(s) 30. Data 230 may include various fields, e.g., a layout 232 field for cataloguing one or more layouts 30 certain products, rules 234 (e.g., “design rules” discussed herein) in the form of a listing of metrics for evaluating whether the design of each layout 30 is acceptable (based on parameters such as, e.g., structure size, structure width and/or length, margin size, etc.) for defining minimum and/or maximum physical parameters for structures in layout 30. Rules 234 may include or accompany logic for determining whether layout(s) 30 and/or portions thereof are compliant with the various requirements set forth in rules 234. Other types of rules 234 and/or parameters for comparison, where desired or applicable, also may be included in data 230. Other rules and/or forms of reference measurements, values, etc., may additionally or alternatively be stored in different fields of data 230. Data 230 may include one or more thresholds 236 for determining whether layout(s) 30 and any structures 32 therein are eligible for compaction. For instance, where rule(s) 234 define a critical dimension (e.g., fifty nanometers (nm)) for two adjacent features, threshold(s) 236 may define an additional separation distance of twenty nm. Any structure(s) 32 having a separation distance of less than the amount defined in threshold(s) 236 (e.g., twenty nm) may be deemed ineligible for further compaction, whereas any structure(s) 32 complying with rule(s) 234 and having characteristics exceeding threshold(s) 236 are deemed eligible for further compaction by modifying layout(s) 30. Threshold(s) 236 may be imposed externally on layout data 232 and rules 234 via layout analysis program 254, and thus may be separate from any generalized rules for any product and/or group of products to be manufactured. Layout adjustment system 220 and modules 222, 224, 226, thereof may cross-reference and apply data within data 230 to implement various processes according to the disclosure, e.g., determining whether certain adjacent structures in layout(s) 30 exceed rules 234 by threshold(s) 236, determining whether changing the position of structures in layout(s) 30 maintains compliance with rules 234, and where applicable providing modified layout(s) 242.

In addition to proposing and implementing modifications to layout 30 by reference to data 230, layout adjustment system 220 may manipulate, interpret, and analyze various forms of information in library 280, including one or more existing layout(s) 30 for one or more individual mask layers or products. In addition, layout adjustment system 220 may generate modified layout(s) 242 to enable manufacturing of modified layout(s) 242 in library 280. In further embodiments, layout analysis program 254 may generate a set of instructions which in turn create modified layout(s) 242 from layout(s) 30 on library 280. Library 280 may form part of, or otherwise may be communicatively coupled to, computing device 204 through any individual or combination of physical and/or wireless data coupling components discussed herein. Some attributes of layout(s) 30 and/or modified layout(s) 242 may be converted into a data representation (e.g., a data matrix with several values corresponding to particular attributes) and stored electronically, e.g., within library 280, memory 212 of computing device 204, storage system 214, and/or any other type of data cache in communication with computing device 204.

Images and/or other representations of layout(s) 30 may additionally or alternatively be converted into data inputs or other inputs to layout analysis program 254 with various scanning or extracting devices, connections to independent systems (e.g., library 280), and/or manual entry of a user. As an example, e.g., a user of computing device 204 could manually input layout(s) 30 and/or other forms of information to layout analysis program 254. Layout analysis program 254 of computing device 204 may output modified layout(s) 242, and in some cases may automatically adjust operation of manufacturing tool(s) 260 based on modified layout(s) 242.

Computer system 202 may be operatively connected to or otherwise in communication with manufacturing tool(s) 260 having one or more manufacturing devices configured to construct IC masks from layouts 30 and modified layouts 242, e.g., as instructed by layout adjustment system 220 to produce modified layout(s) 242 from layout(s) 30 as discussed herein. Computer system 202 may be embodied as a unitary device in a semiconductor manufacturing plant coupled to manufacturing tool 260 and/or other devices or may be multiple devices each operatively connected together to form computer system 202. Embodiments of the present disclosure may thereby include using layout analysis program 254 to convert layout(s) 30 into modified layout(s) 242 by identifying structures that comply with rules 234, and exceed rules by threshold(s) 236, to automatically propose modifying the position(s) of structures 32 such that they remain compliant with rule(s) 234 but reduce the surface area and/or separation distance within layout 30 to provide modified layout(s) 242. As discussed herein, embodiments of the present disclosure may provide instructions for adjusting manufacturing tool(s) 260 based on modified layout(s) 242, e.g., based on where certain structures are located, modified, or removed.

Where computer system 202 includes multiple computing devices, each computing device may have only a portion of layout analysis program 254 and/or layout adjustment system 220 (including, e.g., modules 222, 224, 226) fixed thereon. However, it is understood that computer system 202 and layout adjustment system 220 are only representative of various possible equivalent computer systems that may perform a process described herein. Computer system 202 may obtain or provide data, such as data stored in memory 212 or storage system 214, using any solution. For example, computer system 202 may generate and/or be used to generate data from one or more data stores, receive data from another system, send data to another system, etc.

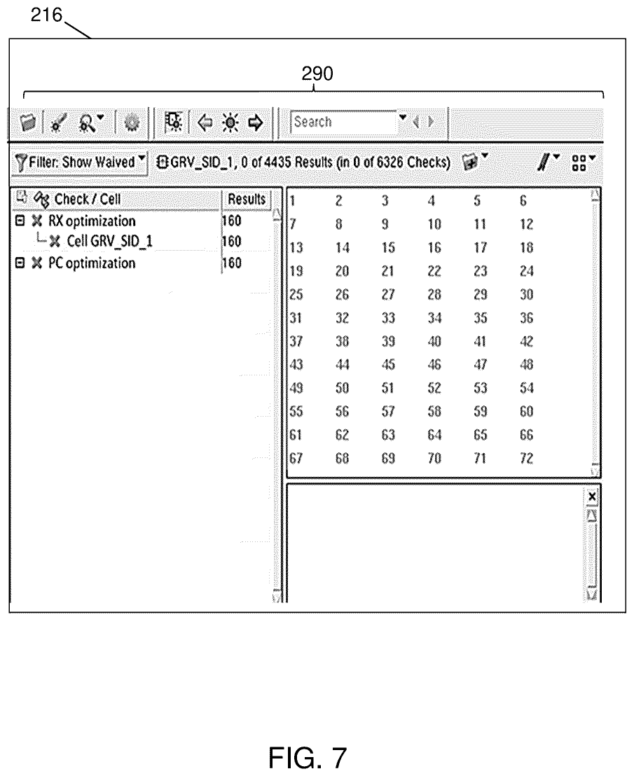

Referring to FIGS. 6 and 7 together, computer system 202 may implement methods of the disclosure by displaying the results of various analysis steps (e.g., determining whether modifying physical parameters for structures 32 (FIG. 1) to be less than the threshold amount maintains compliance with design rules) via an interface 290 (FIG. 7 only). Interface 290 may be shown using I/O device 216 (FIG. 6 only) and/or other components coupled to computer system 202 (FIG. 6 only) via I/O component 210 (FIG. 6 only). Interface 290, during operation, may provide a visual indication of which structures 32, portions of layout 30 (FIG. 6 only), and/or other aspects of modified layout 242 (FIG. 6 only) may comply or not comply with rule(s) 234 (FIG. 6 only). In some cases, interface 290 can visually indicate which portions of modified layout 242 differ from layout 30 and/or whether such portions remain compliant with rule(s) 234. In other cases, a user may interface with interface 290 (e.g., via I/O device 216, I/O component 210, etc.) to confirm whether modified layout 242 maintains compliance with rule(s) 234 and/or whether to manufacture a device using all, none, or some of the modifications in modified layout 242. In the example of FIG. 7, two example structures (i.e., “RX” and “PC” referring to different portions of a standard cell in layout 30) are indicated as not being compliant with rules 234 if modified as set forth in modified layout 242. In the cases where such modifications are compliant with rules 234, the “X” indicator may be a check mark or similarly contrasting symbol. Although the various modifications are shown in an outline list format in FIG. 7, interface 290 may take a variety of forms including maps, charts, graphs, etc. Interface 290 thus may enable display and consideration of multiple possible modifications to structures 32 in modified layout 242 simultaneously.

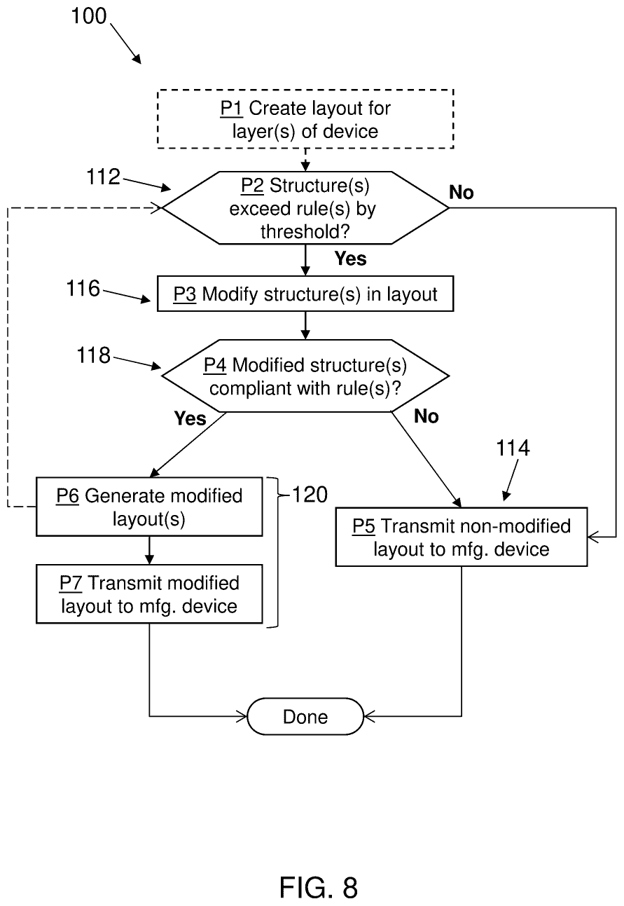

Turning to FIGS. 1, 2, 6, and 8 together, illustrative processes are shown for creating modified layout(s) 242 from layout(s) 30, and/or to manufacture a device from layout(s) 30, 242 with more compactness (i.e., less space between structures 32 and hence lower total surface area). The illustrative flow diagram shown in FIG. 8 is an expanded format of the general flow diagram depicted in FIG. 2, and thus represents one possible ordering of processes that together may define operations 112, 114, 116, 118, 120 discussed herein. The steps and processes depicted in FIG. 8 may be implemented, e.g., with components of layout analysis program 254, one or more modules 222, 224, 226, 228 of layout adjustment system 220, and/or other components of computer system 202 described herein by example. A single and/or repeated execution of the processes discussed herein may allow for repeated use of manufacturing tool(s) 260 to manufacture masks for various layers and products to provide less surface area in devices (or portions thereof) formed from layout(s) 30, 242. In the example processes discussed herein, layout(s) 30 and modified layout(s) 242 generated therefrom will generally be described as including at least two adjacent structures 32, with the total number of adjacent structures 32 differing at each implementation of method 100. That is, each structure 32 under analysis may be compared with one adjacent structure 32 or multiple adjacent structures 32, based on the relevant location in layout 30. It is also understood that the present disclosure may be implemented with respect to multiple structures 32 in layout 30, or on multiple layouts 30 simultaneously and/or sequentially, with each layout's 30 structures 32 having any conceivable dimensions, being in any conceivable number, etc.

In initial or preliminary phases of operation, method 100 optionally may include process P1 of creating (or otherwise obtaining) layout 30 for one or more layers of a device, e.g., any conceivable device incorporating IC structures therein. Layout 30 may include at least one structure 32 adjacent at least one other structure 32, such that there is separation distance 34 between the adjacent structures 32 in layout 30. Method 100, as discussed herein, may entail: determining whether any physical parameters complying with rules 234 (e.g., DRC rules 106 and/or reversed logic DRC 110) also exceed such rules by a threshold amount (process P2); determining whether adjusting such physical parameters to be less than the threshold amount maintains compliance with rules 234 (processes P3-P4); and submitting a modified or non-modified layout for manufacture based on these determinations (processes P6-P7 or P5). In some implementations, process P1 may be implemented before and/or independently of operations 112, 114, 116, 118, 120 and hence may be omitted (i.e., it is shown in dashed lines). Hence, in some cases, process P1 may be performed by another party before methods of the disclosure are implemented, in which case any other processes described herein may be implemented on a pre-existing layout 30 without significant differences.

In process P2, modules 221 of layout adjustment system 220 may implement operation 112 of determining whether one or more physical parameters of layout(s) 30 and/or structures 32 therein exceed rule(s) 234 by a threshold amount. The threshold amount may be predetermined in threshold filed 236 of data 230, and/or may be calculated via calculator 222 as a preliminary sub-process of implementing process P2. In any event, determinator 226 of layout adjustment system 220 may determine that one or more structure(s) 32 under analysis in layout 30 have physical parameters that exceed, or do not exceed, rule(s) 234 by at least the threshold value. In the case where no structure(s) 32 exceed rule(s) 234 by the threshold value, the method may continue to operation 114 (i.e., implemented via process P5 discussed elsewhere herein). In the case where one or more structure(s) 32 exceed rule(s) 234 by the threshold value, the method may continue to operation 116 to modify structure(s) 32 in layout 30.

In process P3, calculator 222 or other modules 221 of layout adjustment system 220 may implement operation 116 of modifying one or more structure(s) 32 in layout 30. The modifying may include, e.g., calculating or otherwise selecting new coordinate positions for structure(s) 32, adjusting dimension(s) S, pitch D, and/or other physical parameters of structure(s) 32 in layout 30 according to any desired adjustment. Such adjustments may be predetermined, selected via one or more users, and/or may be calculated in real-time, e.g., via module(s) 221. Operation 116, implemented via process P3, thus may include changing the size, shape, location, etc., of structures 32 in layout 30 by predetermined or user-chosen amounts. In further examples, process P3 may include using modules 221 of layout adjustment system 220 to automatically generate one or more proposed modifications to layout 30 based on the physical parameters under analysis, and/or other properties such as the amount by which such attributes exceed their respective threshold(s), etc.

After modifying structure(s) 32 in layout(s) 30, method 100 may continue to process P4 of determining whether the modified structure(s) 32 and/or other features of layout 30 remain compliant with rule(s) 234. Process P4 thus may be an implementation of operation 118 discussed elsewhere herein. For instance, changing the position of one structure 32 to be closer to an adjacent structure may also move the same structure 32 too close to another structure 32, thereby violating other DRC rules 106 for layout 30. Similarly, reducing a dimension S of structure 32 also may change the pitch D relative to an adjacent structure 32 and/or the size of separation distance 34. These changes, in some cases, may not comply with rule(s) 234 even if the modification itself is compliant with design rules. Process P4 thus may include re-examining, via determinator 226 and/or other modules 221 of layout adjustment system 220, whether layout 30 as a whole remains compliant with rule(s) 234 once one or more structure(s) 32 therein have been modified. Where the modified layout(s) 30 is/are not compliant with DRC rules 106 (i.e., “No” at process P4), the method may proceed to process P5 of transmitting the non-modified layout (i.e., implementing operation 114). Process P5 may include reverting any modifications to layout 30 deemed non-compliant with rules 234, and optionally, flagging or marking off such modifications as violating design rules 234 to prevent their consideration in future implementations. In process P5, layout 30 is transmitted without the proposed modifications under analysis and thus is considered to be a non-modified layout. Where the modified layout(s) 30, portions thereof, and/or structure(s) 32 are compliant with DRC rules 106 after modifying layout(s) 30 and/or structure(s) 32 (i.e., “Yes” at process P4), the method may proceed to processes P6 and P7 (collectively implementing operation 120) of transmitting modified layout(s) 242 for manufacture.

In some embodiments, operation 120 of submitting modified layout 242 for manufacture may include multiple processes, e.g., processes P6 and P7 discussed herein. In process P6, module(s) 221 of layout adjustment system 220 may convert layout(s) 30 into modified layout(s) 242, thereby producing a new design for a product with a lower surface area and/or other benefits to manufacturability or operability. Following the generation of modified layout 242, methods of the disclosure optionally may return to process P2 for further analysis of other layout(s) 30 and/or re-analysis of the same layout(s) 30 (e.g., as shown in dashed lines). The generating of modified layout 242 in process P6, in some cases, may include flagging or “marking off” layout 30 and/or structures 32 therein as having been modified for further compaction, e.g., when desired to prevent re-analysis of layout 30 in fabrication and/or analysis of subsequent products. In addition or alternatively, modified layout(s) 242 may be associated with the original version of layout(s) 30 for ease of indexing and/or to accelerate subsequent analysis and/or processing of similar layout(s) 30 or structure(s) 32. Process P7 may include submitting modified layout 242, once generated, to library 280 and/or manufacturing tool(s) 260. Manufacturing tool(s) 260 thereafter may manufacture one or more product units via modified layout 242, and without violating rule(s) 234 as a result of determining in process P4 of whether the modifications to layout 30 violate rule(s) 234.

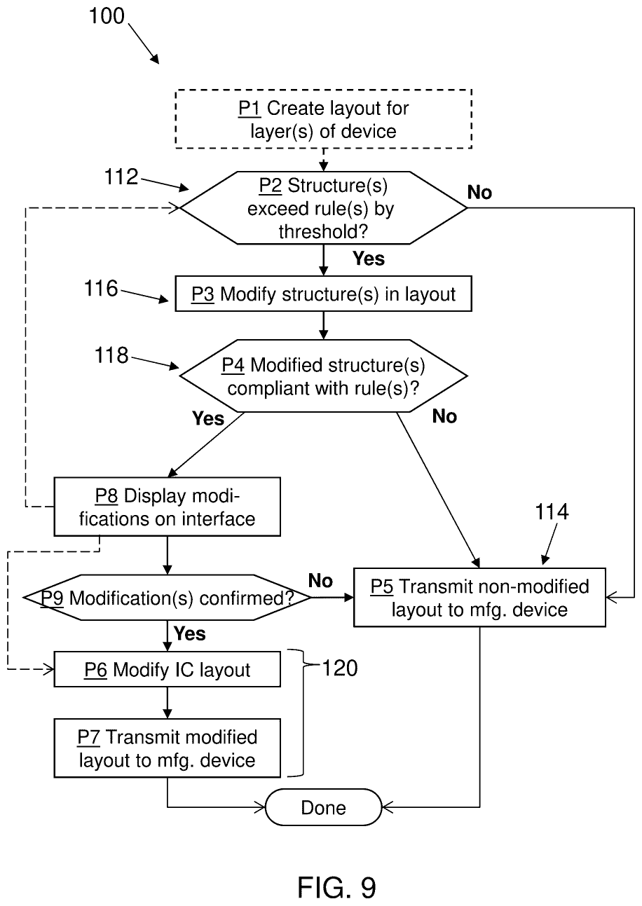

Referring to FIGS. 1, 2, 6, 7, and 9 together, further implementations of method 100 may include additional processes P8 and P9 of providing interface 290 (FIG. 7) to enable a visual indication of possible modifications, and/or to allow user control of whether layout(s) 30 are modified even when such modifications comply with rule(s) 234. Processes P8 and P9 may be implemented following operation 118 (e.g., process P4), and before any processes included within operation 120 (e.g., processes P6, P7), but it is understood that processes P8 and/or P9 may be implemented in other phases of method 100 or as a set of parallel processes. Where modifications to layout(s) 30 and/or structure(s) 32 are deemed compliant with rule(s) 234 in process P4 (i.e., “Yes” in process P4), method 100 may include displaying the compliant modifications to a user via interface 290. Interface 290 may display possible modifications in the form of a list, map, chart, graph, and/or any conceivable format for contextualizing possible changes to layout 30. In some cases, interface 290 simply may display the modifications in layout 30 to a user, and thereafter proceed to operation 120 of creating modified layout 242 and submitting modified layout 242 to manufacturing tool(s) 260 and/or library 280 (e.g., as shown in dashed lines).

In embodiments where possible changes require user approval before modified layout(s) is/are generated, method 100 may include process P9 of determining whether a user confirms (i.e., “user confirmation” or simply “confirmation” of) one or more possible modifications to layout 30 that do not violate design rules. Where no modifications are approved (i.e., “No” at process P9), the method may instead proceed to operation 114 (e.g., process P5) of transmitting layout 30 for manufacture without modifications. Otherwise, where a user approves one or more modifications proposed in interface 290 (i.e., “Yes” at process P9), the method may continue to operation 120 (e.g., processes P6, P7) substantially as discussed elsewhere herein. Upon completing operation(s) 114 and/or 120 where applicable, the method may conclude (“Done”), or may be repeated for other layout(s) 30 for the same product or different products.

Embodiments of the disclosure may provide various technical and/or commercial advantages, examples of which are discussed herein. Methods of the disclosure are operable to reduce the surface area of a product design by reconfiguring design rule logic to check for overcompliance, thereby identifying structures within a layout that can be compacted into a smaller surface area. Embodiments of the disclosure, in addition, can be used for product designs that have not yet been manufactured as it need not rely on verification data to account for possible violation of design rules. Embodiments of the disclosure also enable the creation and maintenance of a data library to inform further design and/or modification of other products, particularly where those products include the same or similar portions of a layout therein. To prevent design defects, embodiments of the disclosure re-examine whether possible modifications remain compliant with design rules to retain manufacturability. These benefits, in turn, improve manufacturability and reduce the size of other products using the same, or similar, portions of a layout.

As will be appreciated by one skilled in the art, aspects of the present disclosure may be embodied as a system, method, or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, aspects of the present invention may take the form of a computer program product embodied in one or more computer readable medium(s) having computer readable program code embodied thereon.

Any combination of one or more computer readable medium(s) may be used. A computer readable storage medium may be, for example, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that may contain or store a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing. Computer program code for carrying out operations for aspects of the present invention may be written in any combination of one or more programming languages, including an object oriented programming language such as Java, Python, Smalltalk, C++ or the like and conventional procedural programming languages, such as the “C” programming language or similar programming languages, e.g., verification languages such as Calibre, ICV, and/or PVS. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described above with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that may direct a computer, other programmable data processing apparatus, or other devices to function in a particular manner, such that the instructions stored in the computer readable medium produce an article of manufacture including instructions which implement the function/act specified in the flowchart and/or block diagram block or blocks. The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowcharts and block diagrams in the Figures illustrate the layout, functionality, and operation of possible implementations of systems, methods, and computer program products according to various embodiments of the present invention. In this regard, each block in the flowchart or block diagrams may represent a module, segment, or portion of code, which includes one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, may be implemented by special purpose hardware-based systems that perform the specified functions or acts, or combinations of special purpose hardware and computer instructions.

As used herein, the term “configured,” “configured to” and/or “configured for” may refer to specific-purpose patterns of the component so described. For example, a system or device configured to perform a function may include a computer system or computing device programmed or otherwise modified to perform that specific function. In other cases, program code stored on a computer-readable medium (e.g., storage medium), may be configured to cause at least one computing device to perform functions when that program code is executed on that computing device. In these cases, the arrangement of the program code triggers specific functions in the computing device upon execution. In other examples, a device configured to interact with and/or act upon other components may be specifically shaped and/or designed to effectively interact with and/or act upon those components. In some such circumstances, the device is configured to interact with another component because at least a portion of its shape complements at least a portion of the shape of that other component. In some circumstances, at least a portion of the device is sized to interact with at least a portion of that other component. The physical relationship (e.g., complementary, size-coincident, etc.) between the device and the other component may aid in performing a function, for example, displacement of one or more of the device or other component, engagement of one or more of the device or other component, etc.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
identifying, within an integrated circuit (IC) layout, a structure having a physical parameter compliant with a design rule for the layout, and exceeding the design rule by a threshold amount;
determining whether modifying the physical parameter for the structure to be less than the threshold amount maintains compliance with the design rule; and
in response to determining that modifying the physical parameter for the structure to be less than the threshold amount maintains compliance with the design rule:
modifying the IC layout, and
transmitting the modified IC layout to a manufacturing device.

2. The method of claim 1, further comprising transmitting a non-modified IC layout to the manufacturing device in response to the modifying not maintaining compliance with the design rule.

3. The method of claim 1, further comprising repeating the identifying for a plurality of structures and a plurality of design rules for the layout, wherein the determining is relative to each of the plurality of structures and each of the plurality of design rules.

4. The method of claim 3, further comprising displaying a result of the determining for each of the plurality of structures and the plurality of design rules in an interface.

5. The method of claim 4, wherein the modifying is further in response to a confirmation, via the interface, that the modifying maintains compliance with the design rule.

6. The method of claim 1, wherein the physical parameter includes one of a dimension, a spacing, a surface area, an enclosure, an overlap, or an overlap relative to dimensionality, for the structure.

7. The method of claim 1, wherein modifying the IC layout reduces a surface area of the IC layout.

8. A computer program product stored on a computer readable storage medium, the computer program product comprising program code, which, when being executed by at least one computing device, causes the at least one computing device to:
identify, within an integrated circuit (IC) layout, a structure having a physical parameter compliant with a design rule for the layout and exceeding a design rule for the structure by a threshold amount;
determine whether modifying the physical parameter for the structure to be less than the threshold amount maintains compliance with the design rule; and
in response to determining that modifying the physical parameter maintains compliance with the design rule:
modify the IC layout, and
transmit the modified IC layout to a manufacturing device.

9. The computer program product of claim 8, further comprising program code for causing the at least one computing device to transmit a non-modified IC layout to the manufacturing device in response to the modifying not maintaining compliance with the design rule.

10. The computer program product of claim 8, further comprising program code for causing the at least one computing device to repeat the identifying for a plurality of structures and a plurality of design rules for the layout, wherein the determining is relative to each of the plurality of structures and each of the plurality of design rules.

11. The computer program product of claim 10, further comprising program code for causing the at least one computing device to display a result of the determining for each of the plurality of structures and the plurality of design rules in an interface.

12. The computer program product of claim 11, further comprising program code for causing the at least one computing device to wherein the modifying is further in response to a confirmation, via the interface, that the modifying maintains compliance with the design rule.

13. The computer program product of claim 8, wherein the physical parameter includes one of a dimension, a spacing, a surface area, an enclosure, an overlap, or an overlap relative to dimensionality, for the structure.

14. The computer program product of claim 8, wherein modifying the IC layout reduces a surface area of the IC layout.

15. A system comprising:
a computing device;
an I/O component operatively coupled to the computing device; and
a memory operatively coupled to the computing device,
wherein the computing device includes logic and is configured to perform a method including:
identifying, within an integrated circuit (IC) layout, a structure having a physical parameter compliant with a design rule for the layout, and exceeding a design rule for the structure by a threshold amount;
determining whether modifying the physical parameter for the structure to be less than the threshold amount maintains compliance with the design rule; and
in response to determining that modifying the physical parameter maintains compliance with the design rule:
modifying the IC layout, and
transmitting the modified IC layout to a manufacturing device.

16. The system of claim 15, wherein the method further includes transmitting a non-modified IC layout to the manufacturing device in response to the modifying not maintaining compliance with the design rule.

17. The system of claim 15, wherein the method further includes repeating the identifying for a plurality of structures and a plurality of design rules for the layout, wherein the determining is relative to each of the plurality of structures and each of the plurality of design rules.

18. The system of claim 17, wherein the method further includes displaying a result of the determining for each of the plurality of structures and the plurality of design rules in an interface.

19. The system of claim 18, wherein the modifying is further in response to a confirmation, via the interface, that the modifying maintains compliance with the design rule.

20. The system of claim 15, wherein the method further includes wherein modifying the IC layout reduces a surface area of the IC layout.
